(19) United States
(12) Patent Application Publication
(10) Pub. No.: US 2026/0276744 A1
(43) Pub. Date: Sep. 17, 2026

(54) HIGH-ACCURACY SENSOR WITH HETEROGENEOUS ARCHITECTURE

(71) Applicant: Allegro MicroSystems, LLC, Manchester, NH (US)

(72) Inventors: Hernán D. Romero, Buenos Aires (AR); Pablo Castro Lisboa, Montevideo (UY); Conrado Rossi, Montevideo (UY)

(73) Assignee: Allegro MicroSystems, LLC, Manchester, NH (US)

(21) Appl. No.: 19/077,163

(22) Filed: Mar. 12, 2025

(51) Int. Cl. G01R 33/00; G01R 33/07; G01R 33/09

(52) U.S. Cl. CPC G01R 33/0005; G01R 33/0041; G01R 33/0082; G01R 33/07; G01R 33/09

(57) ABSTRACT

A sensor, comprising: a first signal path having a first gain, the first signal path including a plurality of magnetoresistance (MR) elements, the first signal path being configured to generate a first signal; a second signal path having a second gain, the second signal path including one or more Hall elements, the second signal path being configured to generate a second signal; a feedback path that is configured to balance the first gain with the second gain, the feedback path including a first feedback coil, a second feedback coil, and a first variable resistor, the first feedback coil being arranged to influence the plurality of MR elements, the second feedback coil being arranged to influence the Hall elements, the first variable resistor being arranged to at least in part adjust an electrical current that is used to drive at least one of the first feedback coil and the second feedback coil.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with proximity, or motion of a target object, or the flow of electric current through a conductor. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a first signal path having a first gain, the first signal path including a plurality of magnetoresistance (MR) elements, the first signal path being configured to generate a first signal based, at least in part, on an output of the MR elements; a second signal path having a second gain, the second signal path including one or more Hall elements, the second signal path being configured to generate a second signal based, at least in part, on an output of the Hall elements; a feedback path that is configured to balance the first gain with the second gain, the feedback path including a first feedback coil, a second feedback coil, and a first variable resistor, the first feedback coil being arranged to influence the plurality of MR elements, the second feedback coil being arranged to influence the Hall elements, the first variable resistor being arranged to at least in part adjust an electrical current that is used to drive at least one of the first feedback coil and the second feedback coil; and combination circuitry that is configured to generate an output signal based, at least in part, on the first signal with the second signal.

According to aspects of the disclosure, a sensor is provided, comprising: a first signal path having a first gain, the first signal path including a plurality of magnetoresistance (MR) elements, the first signal path being configured to generate a first signal based, at least in part, on an output of the MR elements; a second signal path having a second gain, the second signal path including one or more Hall elements, the second signal path being configured to generate a second signal based, at least in part, on an output of the Hall elements; a first feedback coil and a second feedback coil that are configured to balance the first gain with the second gain, the first feedback coil being arranged to influence the plurality of MR elements, and the second feedback coil being arranged to influence the Hall elements; a variable resistor that is configured to at least in part adjust an electrical current used to drive at least one of the first feedback coil and the second feedback coil; and combination circuitry that is configured to generate an output signal by combining the first signal with the second signal.

A sensor, comprising: a first signal path having a first gain, the first signal path including a plurality of magnetoresistance (MR) elements, the first signal path being configured to generate a first signal based, at least in part, on an output of the MR elements; a second signal path having a second gain, the second signal path including one or more Hall elements, the second signal path being configured to generate a second signal based, at least in part, on an output of the Hall elements; a first feedback coil and a second feedback coil that are configured to balance the first gain with the second gain, the first feedback coil being arranged to influence the plurality of MR elements, and the second feedback coil being arranged to influence the Hall elements, a variable current source being configured to drive a given one of the first feedback coil and the second feedback coil; and a controller configured to set a level of an electrical current that is supplied by the variable current source to the given feedback coil in order to cause the first feedback coil and the second feedback coil to balance the first gain with the second gain.

### BRIEF DESCRIPTION OF THE DRAWINGS

The foregoing features may be more fully understood from the following description of the drawings in which:

FIG. 1A is a diagram of an example of a sensor, according to aspects of the disclosure;

FIG. 1B is a graph illustrating aspects of the operation of the sensor of FIG. 1A, according to aspects of the disclosure;

FIG. 1C is a graph illustrating aspects of the operation of the sensor of FIG. 1A, according to aspects of the disclosure;

FIG. 1D is a graph illustrating aspects of the operation of the sensor of FIG. 1A, according to aspects of the disclosure;

FIG. 1E is a graph illustrating aspects of the operation of the sensor of FIG. 1A, according to aspects of the disclosure;

FIG. 2A is a diagram of an example of a sensor, according to aspects of the disclosure;

FIG. 2B is a diagram of an example of a sensor, according to aspects of the disclosure;

FIG. 2C is a diagram of an example of a sensor, according to aspects of the disclosure;

FIG. 2D is a diagram illustrating aspects of the configuration of the sensors of FIGS. 2A-C, according to aspects of the disclosure;

FIG. 2E is a diagram of configuration settings of the sensors of FIGS. 2A-C, according to aspects of the disclosure;

FIG. 2F is a diagram of configuration settings of the sensors of FIGS. 2A-C, according to aspects of the disclosure;

FIG. 2G is a diagram illustrating the configuration of the sensors of FIGS. 2A-C, according to aspects of the disclosure;

FIG. 2H is a diagram of configuration settings of the sensors of FIGS. 2A-C, according to aspects of the disclosure;

FIG. 2I is a diagram of configuration settings of the sensors of FIGS. 2A-C, according to aspects of the disclosure;

FIG. 3A is a diagram of an example of a sensor, according to aspects of the disclosure;

FIG. 3B is a diagram of an example of a sensor, according to aspects of the disclosure;

FIG. 3C is a diagram of an example of a sensor, according to aspects of the disclosure;

FIG. 3D is a diagram illustrating aspects of the configuration of the sensors of FIGS. 2A-C, according to aspects of the disclosure;

FIG. 3E is a diagram illustrating aspects of the configuration of the sensors of FIGS. 2A-C, according to aspects of the disclosure;

FIG. 3F is a diagram of configuration settings of the sensors of FIGS. 2A-C, according to aspects of the disclosure; and

FIG. 3G is a diagram illustrating the configuration of the sensors of FIGS. 2A-C, according to aspects of the disclosure.

### DETAILED DESCRIPTION

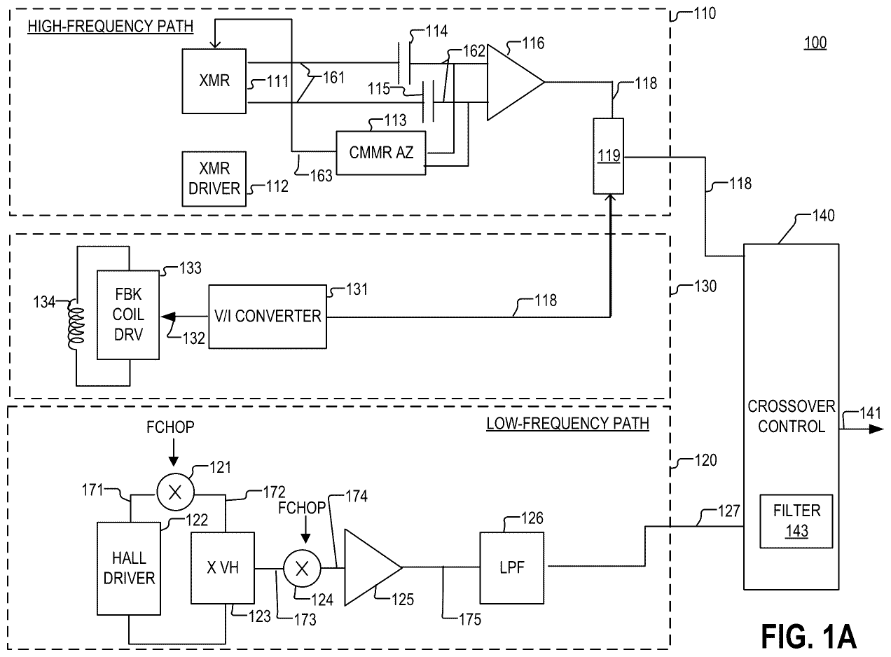

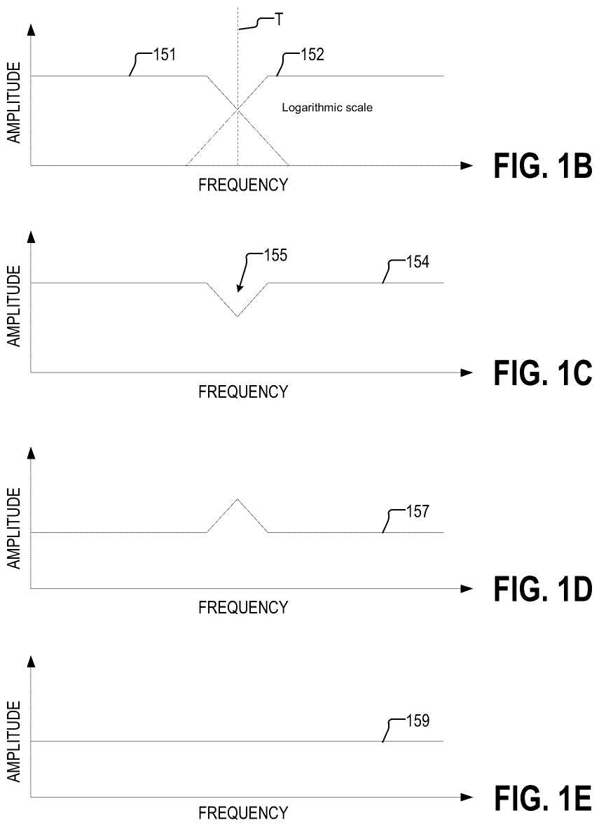

FIG. 1A is a diagram of a magnetic field sensor 100, according to aspects of the disclosure. Sensor 100 may include a position sensor, a current sensor, a speed sensor, and/or any other suitable type of magnetic field sensor.

According to the present disclosure, sensor 100 features a heterogeneous architecture. Specifically, sensor 100 includes a first signal path 110 which utilizes one or more magnetoresistors as its sensing elements, and a second signal path 120 which utilizes one or more Hall elements as its means for sensing magnetic fields. The signal path 110 (i.e., the MR path) provides sensitivity stability by means of feedback path 130 and is an AC-coupled path (e.g., by virtue of having blocking capacitors 114 and 115, which prevent DC signals from passing through). However, the signal path 110 lacks sufficient sensitivity for low-frequency (and/or DC) signals. On the other hand, signal path 120 (i.e., the Hall path) purposely has higher sensitivity with respect to low-frequency signals, but it lacks sufficient sensitivity stability over time, because as the Hall element ages and its accuracy is degraded. On the other hand, the signal path 120 uses frequency chopping to modulate the signal that is output from the Hall elements, and for this reason, it contains low amounts of offset in its output. Conversely, the signal path 110 is susceptible to containing larger amounts of offset in its output. The discussion that follows provides various techniques for combining the outputs of the signal path 110 and the signal path 120 to produce a single output signal, while removing offset that might otherwise be present in the output signal and addressing cross-over issues, such as notching.

According to the example of FIG. 1A, signal path 110 is used to sense magnetic field signals above a frequency threshold T (e.g., 100 KHz) and the second signal path 120 is used to sense magnetic field signals that are below the frequency threshold T. The output signal 118 of the first signal path 110 is combined with the output signal 127 of the second signal path 120 by a crossover control circuit 140 (hereinafter “crossover 140”). The crossover may produce an output signal 141 based on the signals 118 and 127, and provide the output signal 141 to external circuitry that is coupled to sensor 100. The output signal may be indicative of the level of a magnetic field of interest that is being measured with sensor 100. By way of example, the output signal 141 may also be indicative of the level of an electrical current through a conductor, the speed of a target, the position of a target, and/or any other suitable quantity that is normally measured by using magnetic field sensors.

Sensor 100 may include a feedback path 130 whose purpose is to correct for changes in the sensitivity of the signal path 110. Feedback path 130 may include a voltage-to-current (V/I) converter 131, a feedback coil driver 133, and a feedback coil 134. The V/I converter 131 may be configured to receive the signal 118 and generate a control signal 132. The signal 132 is provided to feedback coil driver 133 where it is used by the feedback coil driver 133 to drive the feedback coil 134. Signal 132 may specify the level of electrical current that is required to be passed through the feedback coil 134 and/or the level of feedback magnetic field that is to be generated by the feedback coil.

Signal path 110 may include a driver circuit 112, a sensing bridge 111, a control circuit 113, blocking capacitors 114 and 115, an amplifier 116, and a current converter 119. The sensing bridge 111 may include any suitable type of full-bridge or half-bridge circuit. The sensing bridge 111 may include one or more magnetoresistance (MR) elements. Each of the MR elements may include a giant magnetoresistance (GMR) element, a tunnelling magnetoresistance (TMR) element, and/or any other suitable type of magnetoresistor. Control circuit 113 may include any suitable type of circuit that is configured to equalize the respective resistances of the MR elements in sensing bridge 111. The control circuit 113 may be configured to reduce (or ideally remove) any sensitivity mismatch that is present between the MR elements in the sensing bridge. If there is a sensitivity mismatch in the sensing bridge, the common mode rejection ratio (CMRR) of the sensing bridge 111 would be degraded, so the control circuit 113 may be used to prevent such degradation by adjusting the individual resistances of the MR elements that constitute the sensing bridge 111. Further information about the implementation of control circuit 113 can be found in U.S. patent application Ser. No. 18/527,675, entitled Low Residual Offset Sensor, which is herein incorporated by reference in its entirety.

In operation, sensing bridge 111 may be configured to sense a magnetic field signal and generate a sensing signal 161 in response. Blocking capacitors 114 and 115 may be configured to generate a signal 162 based on signal 161 by removing an offset (which is presented as a DC component) that might be present in signal 161. In addition, the blocking capacitors may implement a high pass filter as a collateral consequence to blocking DC offset that is present in signal 161. Since the size of each capacitor 114 and 115 determines the level of filtering, this is a design variable that can be adjusted depending on the application. The amplifier 116 may be configured to amplify the signal 162 to produce the output signal 118 of the signal path 110. Current converter 119 may be configured to convert signal 118 from a current signal to a voltage signal. The control circuit 113 may be configured to generate a control signal 163 based on the signal 162 and provide the control signal 163 to the sensing bridge 111. Depending on the value of the control signal 163, sensing bridge 111 may adjust the sensitivity of one or more MR elements in sensing bridge 111 to improve the CMRR of sensing bridge 111.

In some implementations, current converter 119 may include circuitry that is configured to convert signal 118 from a current signal into a voltage signal. In such implementations, current converter 119 may be a burden resistor and/or any other suitable type of current-to-voltage converter. In other implementations, current converter 119 may include circuitry that is configured to convert signal 118 from a current signal into a different current signal. In such implementations, current converter 119 may be a current mirror or another similar component. Furthermore, in some implementations, current converter 119 may be omitted. Stated succinctly, the present disclosure is not limited to any specific implementation of current converter 119. According to the present example, current converter 119 is a burden resistor that converts a current signal to a voltage signal.

The second signal path 120 may include a modulator 121, a driver circuit 122, one or more Hall elements 123, a demodulator 124, an amplifier 125, and a low-pass filter (LPF) 126. The Hall driver may include any circuitry that is configured to supply power to the Hall elements 123. According to the present example, Hall elements 123 are vertical Hall elements. However, alternative implementations are possible in which Hall elements 123 are planar Hall elements. The low-pass filter 126 may have a cutoff frequency that is equal to (or otherwise based on) the frequency of threshold T.

In operation, driver circuit 122 may provide a signal 171 to modulator 121. Modulator 121 may modulate signal 171 based on a signal fchop to produce a signal 172, which is subsequently used to drive the Hall elements 123. Hall elements 123 may sense a magnetic field and generate a signal 173 in response. Signal 173 may be demodulated by demodulator 124 based on the signal fchop to produce a signal 174. Signal 174 may be amplified by amplifier 125 to produce a signal 175. Signal 175 may be filtered by LPF 126 to produce the output signal 127.

The operation of the architecture shown in FIG. 1A may be described by equations 1-3 below.

$${S}_{118} = \frac{{B}_{ext ( HF )}}{{K}_{fbkMR} * {d}_{MR}} \cdot {R}_{burden} \qquad ( 1 )$$

$${S}_{127} = {B}_{ext ( LF )} * S * A \qquad ( 2 )$$

$${S}_{141} = {S}_{118} + {S}_{127} \qquad ( 3 )$$

where S₁₁₈ is the value of signal 118, S₁₂₇ is the value of signal 127, S₁₄₁ is the value of signal 141, R_{burden} is the resistance of a burden resistor (e.g., current converter 119 shown in FIG. 1A), B_{ext(HF)} is the magnitude of a high-frequency component of the external magnetic field that is being measured, K_{fbkTMR} is a coupling coefficient representing the transfer of energy between the feedback coil 134 and the sensing bridge (measured in gauss per ampere), d_{MR} is a scaling factor or gain, B_{ext(LF)} is the low-frequency component of the magnetic field that is being measured, and S is the sensitivity of the Hall elements 123, and A the gain of the amplifier 125. In the present example, the frequency components of the magnetic field whose value is below the threshold T are considered low-frequency components and the frequency components whose value is above the threshold T are considered high-frequency components.

FIG. 1B shows a curve 151 which represents the frequency response of signal path 120 (i.e., the frequency response of signal 127), and a curve 152 which represents the frequency response of signal path 110 (i.e., the frequency response of signal 118). Also shown in FIG. 1B is the value of threshold T. The dashed portions of curves 152 and 151 may represent the frequency components that are being filtered by blocking capacitors 114 and 115, and the low-pass filter 126, respectively. Although, in the present example, the dashed portions are filtered in some implementations they may be left unfiltered. Because FIG. 1B features a logarithmic scale, the addition of these portions to the sum of signals 118 and 127 may be negligible. In sum, FIG. 1B shows that the frequency response of signal path 110 slumps towards the end of the low-frequency range (i.e., the range including frequencies that are lower than threshold T), while the frequency response of signal 127 lags at the beginning of the high-frequency range (i.e., the range including frequencies that are larger than the threshold T).

FIG. 1C shows the plot of a curve 154, which represents signal 141, when signal 141 is calculated in accordance with equation 3 above. The example of FIG. 1C assumes that signals paths 110 and 120 have the same gains. As illustrated, curve 154 includes a notch 155 which results from the slump/lag in signals 118 and 127. Having such a notch in the frequency response of crossover 140 is undesirable as it could compromise the accuracy of sensor 100. For this reason, crossover 140 may include a filter 143 which is arranged to rectify the notch. The response of filter 143 is represented by curve 157, which is shown in FIG. 1D. The output of filter 143 is represented by curve 159, which is shown in FIG. 1E. FIG. 1E is provided to illustrate that the application of filter 143 to the sum of the outputs of signal paths 110 and 120 may produce a flat response of sensor 100 across the entire range of frequencies of interest for sensor 100. In some respects, FIGS. 1B-E are provided to illustrate an example of a cross-over issue, which is herein referred to as “notching”, and which is manifested in the combination of signal paths 110 and 120 having a non-uniform frequency response. In the example, of FIG. 1C, the non-uniformity in the combination of signals 118 and 127 (i.e., the non-uniformity in the frequency response of signal 141) is manifested by notch 155.

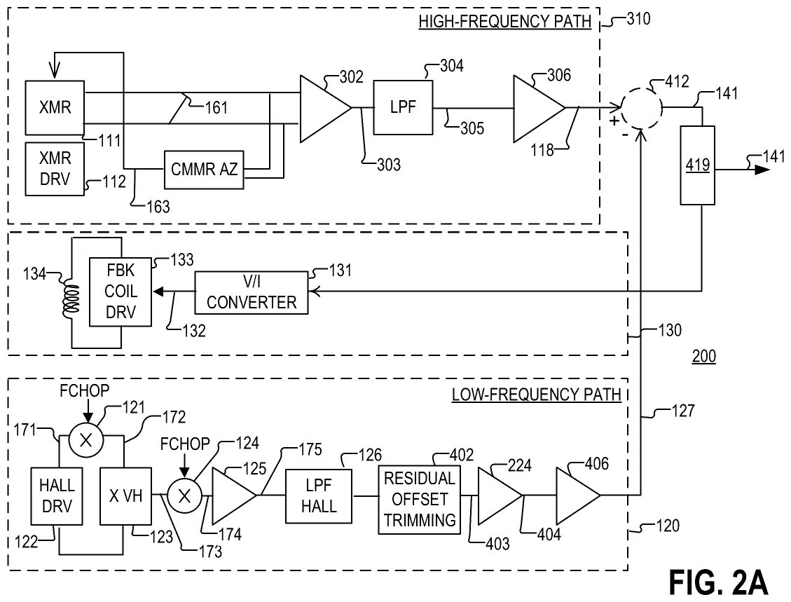

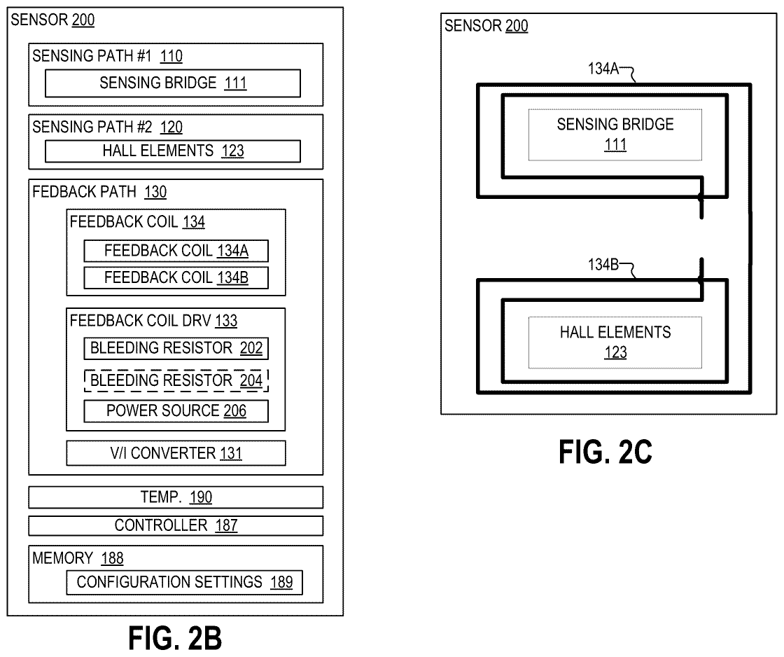

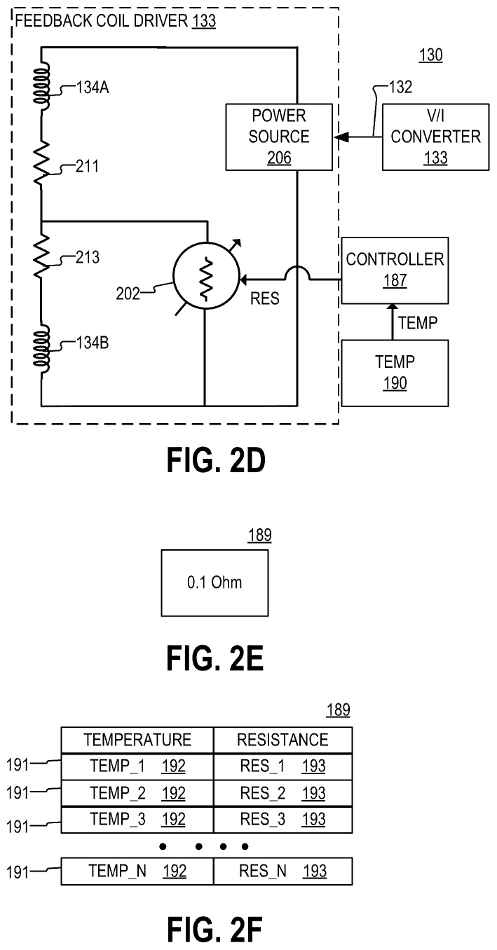

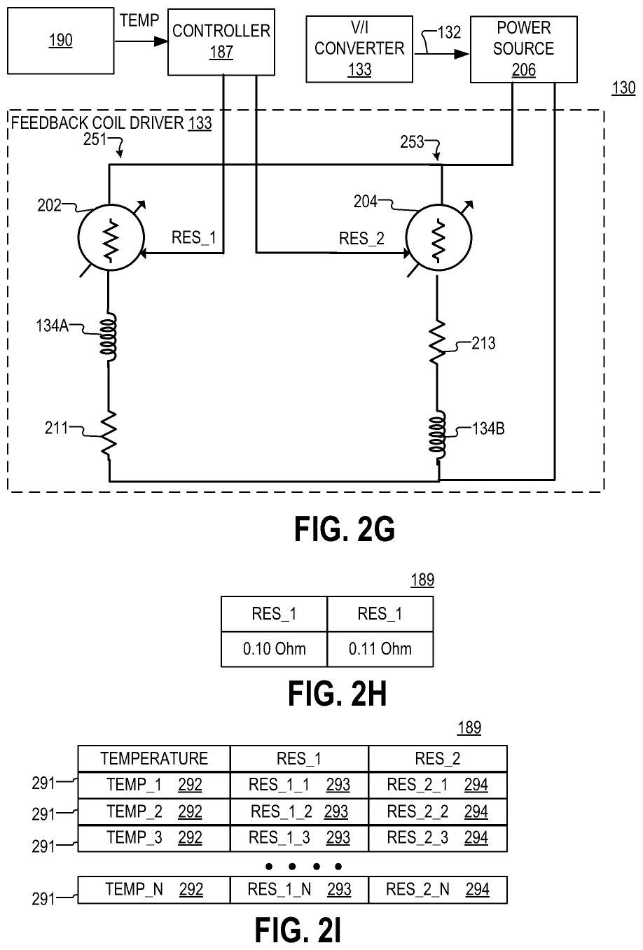

FIG. 2A is a diagram of another implementation of magnetic field sensor 200, according to aspects of the disclosure. Sensor 200 is identical to sensor 100 (shown in FIG. 1A), but for (i) the sensor 200 including a signal path 310 instead of the signal path 110, (ii) the sensor 200 including a summation circuit 412 instead of the crossover 140, (iii) signal path 120 including a trimming module 402 and amplifiers 224 and 406, (iv) and sensor 200 including a current converter 419.

Signal path 310 may include a driver circuit 112, a sensing bridge 111, a control circuit 113, an amplifier 302, an LPF 304, and an amplifier 306. In operation, sensing bridge 111 may be configured to sense a magnetic field signal and generate a sensing signal 161 in response. The amplifier 302 may be configured to amplify the sensing signal 161 to produce an amplified signal 303. The LPF 304 may be configured to filter the signal 303 to produce a signal 304. And the amplifier 306 may be configured to amplify the signal 304 to produce the signal 118.

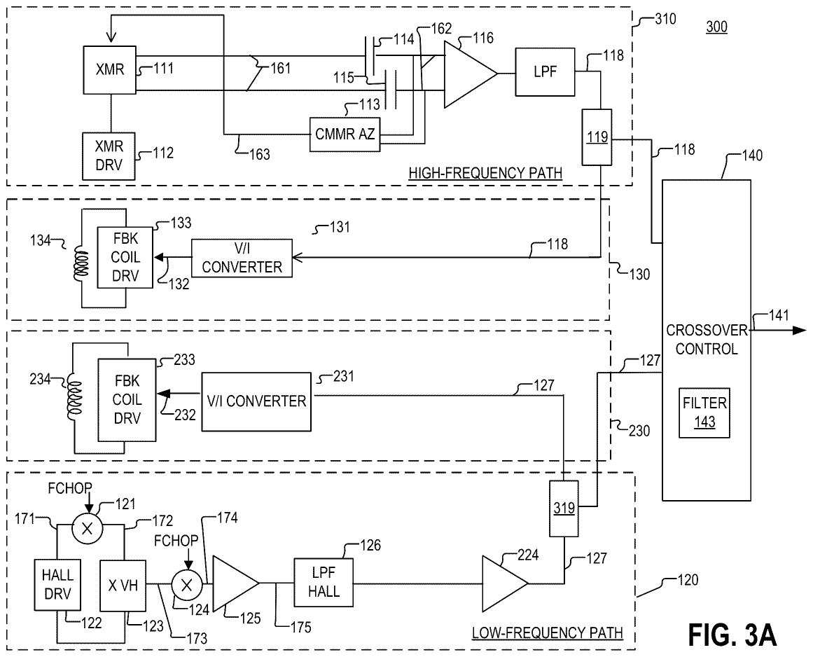

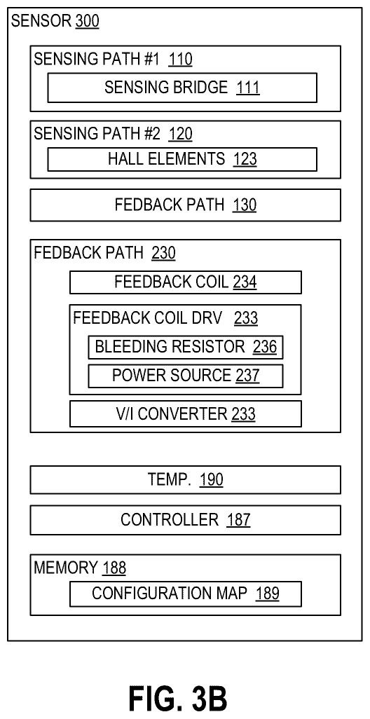

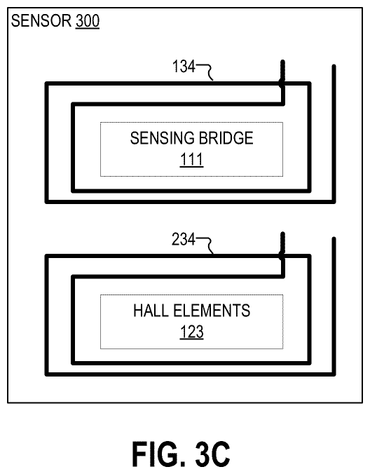

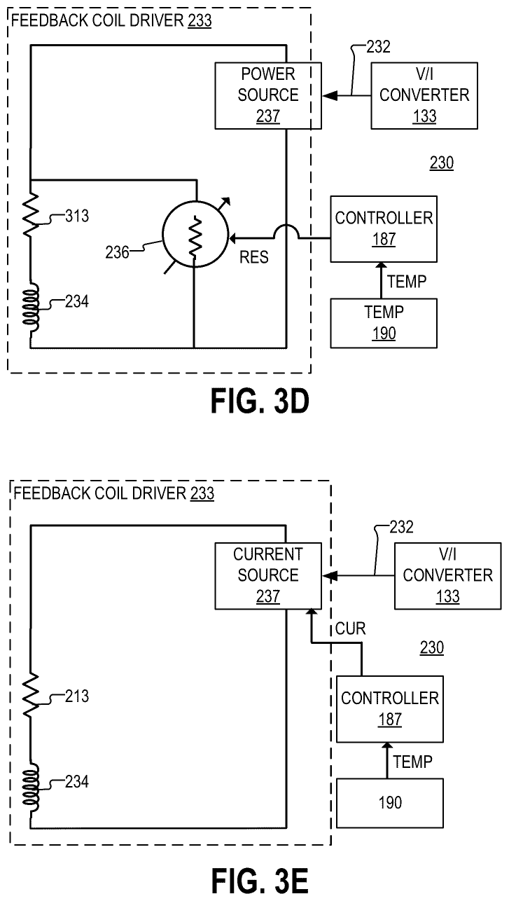

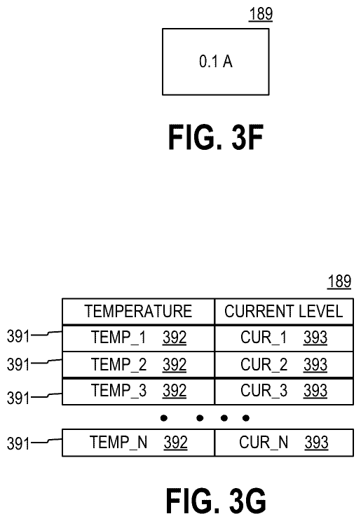

Furthermore, in the example of FIG. 2A, the trimming module 402 in signal path 120 is disposed between the LPF 126 and amplifier 224. Trimming module 402 may include any suitable type of circuit that is configured to remove any residues of offset that is present in the output of LPF 126 after the chopping operation. In some implementations, an extra trimming module, such as the trimming module 402 may be included in any of the designs of signal path 120 that are disclosed with respect to FIGS. 1A and 3A. Trimming module 402 may be configured to receive the output of LPF 126 and generate a signal 403 in response by subtracting an offset value from the output of LPF 126. In some implementations, trimming module 402 may be configured to remove offset from the output of LPF 126, which results from temperature changes, changes in humidity, mechanical stress, or other environmental conditions. Amplifier 224 may amplify the signal 403 to produce an amplified signal 404. And amplifier 406 may amplify the signal 404 to produce the signal 127. In the example of FIG. 2A, amplifier 406 is presented separately from amplifier 224 to make explicit the point that signal path 120 is required to have a higher gain than signal path 310 (over a certain frequency range), in order for signal path 120 to dominate at low frequencies.

Summation circuit 412 may subtract signal 127 from signal 118 to produce the output signal 141.

Current converter 419 may be configured to convert signal 141 from a current signal into a voltage signal. In some implementations, current converter 419 may include circuitry that is configured to convert signal 141 from a current signal into a voltage signal. In such implementations, current converter 419 may be a burden resistor and/or any other suitable type of current-to-voltage converter. In other implementations, current converter 419 may include circuitry that is configured to convert signal 141 from a current signal into a different current signal. In such implementations, current converter 419 may be a current mirror or another similar component. Furthermore, in some implementations, current converter 419 may be omitted. Stated succinctly, the present disclosure is not limited to any specific implementation of current converter 419. According to the present example, current converter 419 is a burden resistor that converts a current signal into a voltage signal.

In the example of FIG. 2A, the feedback path 130 is driven with the output signal 141, rather than with the signal 118 (which is the case with the designs of FIGS. 1A-3). The V/I converter 131 may be configured to receive the signal 141 and generate the control signal 132. Signal 132 may be provided to feedback coil driver 133 where it can be used by the feedback coil driver 133 to drive the feedback coil 134. Signal 132 may specify the level of electrical current that is required to be passed through the feedback coil 134 and/or the level of feedback magnetic field that is to be generated by the feedback coil.

The operation of the architecture shown in FIG. 2A may be described by equations 4-6 below:

$$1 ≪ {A}_{MR} ≪ {A}_{HALL} \qquad ( 4 )$$

$${V}_{off} = ( \frac{{A}_{MR}}{{A}_{HALL}} ) * {V}_{offMR} ≅ 0 \qquad ( 5 )$$

$${S}_{141} = \frac{{B}_{ext}}{d * {K}_{fbk}} \cdot {R}_{burden} + {V}_{off} = \frac{{B}_{ext}}{d * {K}_{fbk}} \cdot {R}_{burden} \qquad ( 6 )$$

where A_{MR} is the gain of signal path 310, A_{HALL} is the gain of signal path 120, Voff is the offset that is present in signal 141, R_{burden} is the resistance of a burden resistor (e.g., current converter 419, shown in FIG. 2A), V_{offMR} is the offset that is present in signal 161, A_{MR} is the gain of signal path 310, A_{HALL} is the gain of signal path 120, d is a scaling coefficient, and K_{fbkMR} is a coupling coefficient that represents the transfer of energy between feedback coil 134 and the sensing bridge 111, and d is a scaling coefficient. Equation 4 indicates that signal path 120 should have a much larger gain than signal path 110. In some implementations, the gain may be 10 times larger, 100 times larger, or 1000 times larger. Equation 5 indicates that the amount of offset that is present in the output signal 141 is proportional to the ratio of the gain of signal path 310 and the gain of signal path 120. Because the gain of signal path 120 is exceedingly larger than the gain of signal path 110, the ratio would approach zero, which in turn would cause the amount of offset that is present in signal 141 to approach zero, as well. In some respects, equation 5 dictates how much larger the gain of signal path 120 should be than the gain of signal path 110. In a typical application, the gain of signal path 110 may be about 100 times larger (e.g., the gain might be in the range of 90-110).

In the design of FIG. 2A, frequency cross-over is still a concern. To deal with this concern, the design of FIG. 2A features a single feedback loop, which is driven by the combination of the outputs of both signal paths. Furthermore, signal path 120, which is in charge of driving low offset since it is chopped and trimmed, will have a larger DC gain than signal path 310. As a result of the gain disparity between signal path 120 and signal path 310, it will be path 120 that will set the output signal 141, while the contribution of signal path 310 will be negligible. Therefore the output signal 141 will be offset-free provided that signal path 120 is offset free. This will be the case until the frequency response of path 120 begins to taper. At that point, signal path 310 will start to kick in to the point its gain will be higher than the gain of signal path 120 (because 120 will be low-pass-filtered at that point). In some respects, as long as the DC gain of signal path 120 is much higher than the DC gain of signal path 310, the offset of signal path 120 will be attenuated at the output.

In some implementations, LPF 126, which is part of signal path 120, may be replaced with a notch filter, which might have a more effective ripple reduction as a result of the frequency chopping that is performed in signal path 120. The notches in the response of the notch filter will be hidden by means of the signal path 310 which at those frequencies will have a much larger gain. In this way, by means of a single feedback loop, small frequency response ripples due to cross-over issues between signal path 310 and signal path 120 will be completely hidden in the closed loop response. In other words, the feedback loop may mask any gain changes (or uneven regions in the frequency response) of both signal path 310 and signal path 120.

FIG. 2B is a schematic diagram of sensor 200, according to aspects of the disclosure. FIG. 2B is intended to provide additional detail about the construction of the feedback path 130.

In the example of FIG. 2B, sensor 200 includes the sensing path 310, the sensing path 120, the feedback path 130, a temperature sensor 190, a controller 187, and a memory 188. The sensing path 310 includes the sensing bridge 111, the sensing path 120 includes the Hall elements 123, and the feedback path 130 includes the feedback coil 134, the feedback coil driver 133, and the V/I converter 131.

Temperature sensor 190 may include any temperature sensor that is configured to measure the temperature (e.g., internal temperature or ambient temperature) of sensor 200. Controller 187 may include digital logic, a general-purpose processor, a special purpose processor, and/or any other suitable type of processing circuitry. Memory 188 may include any suitable type of volatile or non-volatile memory, such as a flash memory or a random-access memory (RAM). Memory 188 may be configured to store configuration settings 189. As is discussed further below, the configuration setting 189 may specify resistance values for bleeding resistors that are part of the feedback path 130.

In the example of FIG. 2B, the feedback coil 134 is split into two portions, which are herein referred to as feedback coil 134A and 134B. Each feedback coils 134A and 134B may be implemented as a conductive trace that is formed on the same silicon die as the remaining components of sensor 100. Each of feedback coils 134A and 134B may include a plurality of turns. According to the present example, feedback coils 134A and 134B are identical to each other—i.e., they include the same number of turns and have the same physical dimensions. However, alternative implementations are possible in which feedback coil 134A has a different number of turns than feedback coil 134B and/or different physical dimensions.

In the example of FIG. 2B, the feedback coil driver 133 is provided with a bleeding resistor 202, and optionally with a bleeding resistor 204. Furthermore, feedback coil driver 133 is provided with a power source 206. The power source 206 may include a voltage source, a current source, and/or any other suitable type of electronic circuitry that is configured to provide, at least in part, the signal that is used to drive the feedback coils 134A-B.

FIG. 2C is a schematic diagram of sensor 200, according to aspects of the disclosure. FIG. 2C is provided to illustrate that feedback coil 134A is arranged to impart a first feedback magnetic field on sensing bridge 111 and feedback coil 134B is arranged to impart a second feedback magnetic field on Hall elements 123. The first feedback magnetic field (generated by feedback coil 134A) may be sensed by sensing bridge 111, and ideally not sensed at all (or sensed to a much lesser extent) by Hall elements 123. The second feedback magnetic field (generated by feedback coil 134B) may be sensed by Hall elements 123, and ideally not sensed at all (or sensed to a much lesser extent) by sensing bridge 111. In other words, feedback coil 134A may be dedicated to influencing the operation of sensing bridge 111, while feedback coil 134B may be dedicated to influencing the operation of Hall elements 123. In the example of FIG. 2C, feedback coil 134A is arranged to surround sensing bridge 111, and feedback coil 134B is arranged to surround Hall elements 123. However, it will be understood that any alternative spatial arrangement can be used instead (in some implementations) in which feedback coil 134A is situated in greater proximity to sensing bridge 111 than it is to Hall elements 123, and feedback coil 134B is situated in greater proximity to Hall elements 123 than sensing bridge 111. In general, feedback coil 134A may be arranged to influence sensing bridge 111, and feedback coil 134B may be arranged to influence Hall elements 123. This means that feedback coils 134A-B are so positioned and/or otherwise configured that the magnetic field generated by feedback coil 134A is stronger than the magnetic field generated by feedback coil 134B at the location of sensing bridge 111, and the magnetic field generated by feedback coil 134B is stronger than the magnetic field generated by feedback coil 134A at the location of Hall elements 123. This can be achieved by placing feedback coil 134A in greater proximity to sensing bridge 111 than feedback coil 134B and placing feedback coil 134B in greater proximity to Hall elements 123 than feedback coil 134A, and/or in any other suitable manner. In the example of FIG. 2B, feedback coil 134 includes two portions-namely feedback coils 134A and 134B, which are coupled in series with a power source. However, in some implementations, feedback coils 134A and 134B may be coupled in parallel to the power source.

FIGS. 2A-C provide an example of a hybrid multipath magnetic feedback architecture, with a main goal of stabilizing the offset of the MR channel (i.e., the offset of signal path 310). Further examples of hybrid multipath magnetic feedback architectures are provided in U.S. patent application Ser. No. 18/922,607, entitled “HIGH ACCURACY SENSOR WITH HETEROGENEOUS ARCHITECTURE,” which is herein incorporated by reference in its entirety. However, such hybrid architectures, either using one or two feedback coils will have a discrepancy or mismatch between MR and Hall magnetic coupling factors. This is inherent to the geometry of the TMR and Hall devices, which, for the same metal layers that can be potentially used for integrating a feedback coil, have different distances to the sensitive portions of the devices, and thus different feedback magnetic fields sensed by each device for the same feedback current.

The operation of the system shown in FIG. 2C may be described by equation 7 below, which can itself be derived from equation 6.

$${S}_{141} = ( \frac{{\overbrace{{B}_{ext}}}^{HF}}{{K}_{fTMR}} + \frac{{\overbrace{{B}_{ext}}}^{LF}}{\text{?} {K}_{fVH}} ) \cdot {R}_{burden} + {V}_{off} \qquad ( 7 )$$

Where S₁₄₁ is signal 141, Bₑₓₜ is the magnetic field that is incident on sensing bridge 111 and Hall elements 123, R_{burden} is the resistance of burden resistor 419 (shown in FIG. 2A), K_{fTMR} is the coupling coefficient between coil portion 134A, and K_{fvH} is the coupling coefficient between coil portion 134B and Hall elements 123. The purpose of equation 7 is to show that in order to obtain a flat frequency response for signal S₁₄₁, K_{fTMR} should be equal to K_{fvH}. This is because, the signal path 310 (associated with K_{fTMR}) is tuned to respond to high-frequency magnetic fields (or magnetic field components) and signal path 120 (associated with K_{fvH}) is tuned to respond to low-frequency magnetic fields.

As noted above, in most practical applications, the coupling coefficients K_{rvH} and K_{fTMR} are unlikely to be exactly equal because differences in the physical characteristics of the MR elements in sensing bridge 111 and the Hall elements 123. For this reason, bleeding resistor 202, and optionally bleeding resistor 204, are introduced to correct for any mismatch that there might be between the coupling coefficients K_{fvH} and K_{fTMR}.

In one aspect, the bleeding resistor 202, and optionally the bleeding resistor 204, may be configured to compensate, at least in part, for any mismatch between a first feedback current corresponding to the coil portion (i.e., coil 134A) acting on sensing bridge 111 a second feedback current corresponding to the coil portion 134B (i.e., coil 134B) acting on Hall elements 123. Specifically, bleeding resistor 202 (and optionally bleeding resistor 204) may be configured to ensure that the feedback current that is produced by feedback loop at the location of sensing bridge 111 is the same or approximately the same as the feedback current that is produced by feedback loop at the location of Hall elements 123. Or put differently, bleeding resistor 202 may be configured to cause the response of sensing bridge 111 to the first feedback loop to match the response to the second feedback loop.

In another aspect, the bleeding resistor 202 and optionally the bleeding resistors 204 may be configured to compensate for disparities between the way in which the sensitivity of sensing bridge 111 and Hall elements 123 changes in response to varying environmental conditions, such as temperature. For example, if the sensitivity of Hall elements 123 decreases to a lesser extent with an increase in temperature than the sensitivity of sensing bridge 111, bleeding resistor 202 could ensure that Hall element loop is driven with a slightly stronger signal that what coil 134B would dictate provided it has larger coupling factor than coil 134A, which in turn would ensure that when sensing bridge 111 takes control, it will do so by setting the same current level as the one it was set on the feedback loop when the Hall elements 123 were taken control of such loop It will be recalled that the first feedback magnetic field is generated by feedback coil 134A and the second feedback magnetic field is generated by feedback coil 134B.

FIG. 2D is a diagram of an example of feedback path 130, according to aspects of the disclosure. In the example of FIG. 2D, feedback path 130, and driver 133 in particular, includes bleeding resistor 202, while bleeding resistor 204 is omitted. Bleeding resistor 202 is a variable resistor (or programmable resistor) whose resistance is set by a controller 187. Specifically, controller 187 is configured to provide bleeding resistor 202 with a signal RES which sets the resistance value of bleeding resistor 202. In the example of FIG. 2D, feedback coils 134A and 134B are coupled in series with each other, and with resistors 211 and 213. The bleeding resistor 202 is coupled in series with feedback coil 134A and in parallel with feedback coil 134B. The power source 206 is configured to supply power (or electrical current) for driving both feedback coil 134A and feedback coil 134B. As noted above, the level of the supplied current may be set based on signal 132. As used throughout the disclosure, the term “variable resistor” refers to any electronic device whose resistance varies in response to a control signal supplied by control circuitry. By way of example, a variable resistor could be a transistor that is operated in its linear region, a switched network of resistors, etc. In the example of FIG. 2D, the bleeding resistor 202 is configured to add to the electrical current that is supplied to feedback coil 134A. However, in an alternative implementation, bleeding resistor 202 may be configured to add to the electrical current that is being supplied to feedback coil 134B.

The value of signal RES may be specified based on configuration settings 189. In one example, as illustrated by FIG. 2E, configuration settings 189 may be a number that is stored in the memory 188 while sensor 200 is still at the factory. The value of the number may be determined as a result of executing a calibration procedure at the factory where sensor 200 is manufactured. The value of the number may specify the resistance value that should be assumed by bleeding resistor 202. In some implementations, controller 187 may retrieve the number from memory, generate the signal RES by converting the number to analog format, and apply the signal RES to bleeding resistor 202 thereby causing the resistance of bleeding resistor 202 to be set to the value indicated by signal RES.

In another example, as illustrated by FIG. 2F, configuration settings 189 may be a table (or another data structure or database) that is stored in the memory 188 (or elsewhere), which maps different resistance values to corresponding temperature values. As illustrated, the table may include a plurality of entries 191. Each entry 191 may include a field 192 and a field 193. In the present example, the value of each field 192 is a temperature value, and the value of each field 193 is a resistance value. In other words, the entries 191 are configured to map each of a plurality of different temperature values to a different corresponding resistance value.

In some implementations, controller 187 may receive a signal TEMP from temperature sensor 190. The signal TEMP may be indicative of the temperature of sensor 200. Next, controller 187 may perform a search of the table to identify an entry 191 that corresponds to the value of signal TEMP. The entry that corresponds to the value of signal TEMP may be one that includes the value of signal temp in field 193. Alternatively, the entry 191 that corresponds to the value of signal TEMP may be one whose field 192 value is the closest to the value of signal TEMP from among all entries 191. Next, controller 187 may retrieve, from the identified entry, the value of field 192 (i.e., retrieve the resistance value that corresponds to the current value of signal TEMP). And finally, controller 187 may generate the signal RES by converting the retrieved value of field 193 to analog format. The signal RES is then applied to a bleeding resistor 202, which causes bleeding resistor 202 to assume the resistance specified by the value of signal RES.

In the example of FIG. 2F, settings 189 map different resistance values to respective temperature values. However, in alternative implementations, settings 189 may map different resistance values to corresponding values of an environmental condition other than temperature. The condition may include stress that is incident on the sensor 200, humidity that is incident on sensor 200, and so forth. Sensor 190 may be a sensor that is arranged to measure the environmental condition that is mapped in settings 189. For example, sensor 190 may include a humidity sensor, or a stress sensor, etc. Although, in the example of FIG. 2F, a look-up table is used to map the value of a signal temp to a resistance value, alternative implementations are possible in which the resistance value is determined by controller 187 evaluating a function that maps the value of signal TEMP to a resistance value. The term “resistance value” as used in the context of settings 189, may refer to any number or alphanumerical string that at least in part specifies the value of signal RES and/or the actual resistance that would be assumed by the bleeding resistor 202 when signal RES assumes the resistance value.

An example of one possible methodology is now described for selecting the value of bleeding resistor 202. In general, the resistance of bleeding resistor 202 should be selected such that equation 8 below holds true:

$${I}_{FBKB} * {R}_{LHall} + {I}_{bleed} = {I}_{FBKA} * {R}_{LTMR} \qquad ( 8 )$$

where I_{FBKB} is the electrical current that is being supplied by power source 206, R_{LHall} is the resistance of resistor 213, I_{bleed} is the electrical current through bleeding resistor 202, I_{FBKA} is the electrical current through feedback coil 134A, and R_{LTMR} is the electrical current through resistor 213.

In order for equation 8 to hold true, equations 9 and 10 must also hold true:

$$( \frac{{B}_{ext}}{{K}_{fVH}} + {I}_{bleed} ) = \frac{{B}_{ext}}{{K}_{fTMR}} \qquad ( 9 )$$

$$( \frac{{B}_{ext}}{{K}_{fVH}} + \frac{{B}_{ext}}{{K}_{fVH}} * {R}_{Lhall} / {R}_{bleed} ) = \frac{{B}_{ext}}{{K}_{fTMR}} \qquad ( 10 )$$

where R_{bleed} is the resistance (or value) of bleeding resistor 202. As noted above, Bₑₓₜ is the external magnetic field that is incident on sensor 100, K_{fvH} is the magnetic coupling coefficient between Hall elements 123 and feedback coil 134B, and K_{fTMR} is the magnetic coupling coefficient between sensing bridge 111 and feedback coil 134A.

Equations 9 and 10 yield equation 11 below:

$${R}_{Lhall} / {R}_{bleed} = ( \frac{{B}_{ext}}{{K}_{fTMR}} - \frac{{B}_{ext}}{{K}_{fVH}} ) \cdot \frac{{K}_{fVH}}{{B}_{ext}} \qquad ( 11 )$$

Equation 11 can be simplified to equation 12 below:

$${R}_{bleed} = \frac{{R}_{Lhall}}{( \frac{{K}_{fVH}}{{K}_{fTMR}} - 1 )} \qquad ( 12 )$$

Equation 11 assumes that K_{rvH} is higher than K_{ITMR}-accordingly, in some implementations, sensor 200 may be configured such that K_{fvH} is higher than K_{fMR} (e.g., by placing feedback coil 134A closer to sensing bridge 111 than feedback coil 134B is placed relative to Hall elements 123. Thus, in some implementations, feedback coils 134A and 134B may be configured so that feedback coil 134B has a slightly higher coupling coefficient with respect to Hall elements 123 than feedback coil 134A does with respect to sensing bridge 111A, after which the bleeding resistor may be set to a value that corrects for the discrepancy while also correcting for any other mismatch between the coupling coefficients that is present (and which is not easily attributable to factors such as physical placement).

FIG. 2G is a diagram of another example of feedback path 130, according to aspects of the disclosure. In the example of FIG. 2G, feedback path 130, and driver 133 in particular, includes a leg 251 and a leg 253, which are coupled in parallel with each other. Leg 251 includes bleeding resistor 202 coupled in series with feedback coil 134A and resistor 211. Leg 253 includes bleeding resistor 204 coupled in series with resistor 213 and feedback coil 134B. In the example of FIG. 1G, both bleeding resistors 202 and 204 are programmable resistors. The resistance of bleeding resistor 202 is set by a signal RES_1 which is provided to bleeding resistor 202 by controller 187. The resistance of bleeding resistor 204 is set by a signal RES_2 that is provided to bleeding resistor 204 by controller 187. The power source 206 is configured to supply power (or electrical current) for driving both bleeding resistors 202 and 204. As noted above, the level of the supplied current may be set based on signal 132.

The value of signals RES_1 and RES_2 may be specified based on configuration settings 189. In one example, as illustrated by FIG. 2H, configuration settings 189 may include a first number that specifies the value of signal RES_1 and a second number that specifies the value of signal RES_2. Both the first and second numbers may be stored in the memory 188 while sensor 200 is still at the factory. The value of the first and second numbers may be determined as a result of executing a calibration procedure at the factory where sensor 200 is manufactured. The first number may specify the resistance value that should be assumed by bleeding resistor 202, and the second number may specify the resistance that should be assumed by bleeding resistor 204. In some implementations, controller 187 may retrieve the first and second numbers from the memory 188, and generate the signals RES_1 and RES_2 by converting the first and second numbers to analog format, respectively. Next, controller 187 may apply the signal RES_1 to bleeding resistor 202 thereby causing the resistance of bleeding resistor 202 to be set to the value indicated by signal RES_1. Similarly, controller 187 may apply the signal RES_2 to bleeding resistor 204 thereby causing the resistance of bleeding resistor 204 to be set to the value indicated by signal RES_2.

In another example, as illustrated by FIG. 2I, configuration settings 189 may be a table (or another data structure or database) that maps different resistance values to corresponding temperature values. As illustrated, the table may include a plurality of entries 291. Each entry 291 may include fields 292, 293, and 294. In any given entry 291, field 292 may include a different temperature value (or a different value of signal temp), field 293 may include a value for signal RES_1, and field 294 may include a value for signal RES_2. In other words, the entries 291 may together map each of a plurality of temperature values to a corresponding pair of values for signals RES_1 and RES_2. In the example of FIG. 2I, configuration settings 189 maps different temperature values to corresponding resistance values. However, in alternative implementations, configuration settings 189 may map the values of another environmental condition to corresponding resistance values. For example, configuration settings may map the resistance values to: (i) humidity values (corresponding to the humidity at the location of sensor 200), (ii) stress values (corresponding to the stress incident on sensor 200), (iii) and/or the values of any another environmental condition that is associated with sensor 200.

In some implementations, controller 187 may receive a signal TEMP from temperature sensor 190. The signal TEMP may be indicative of the temperature of sensor 200. Next, controller 187 may perform a search of the table to identify an entry 291 which corresponds to the value of signal TEMP. The entry may be identified in the manner discussed above with respect to FIG. Next, controller 187 may retrieve, from the identified entry, the value of fields 293 and 294. Next, controller 187 may generate signal RES_1 by converting the value field 293 to analog format. Next, controller 187 may generate signal RES_2 by converting the value of field 294 to analog format.

An example is now provided of another possible methodology for determining the value of bleeding resistors 202 and 204. This methodology involves setting the bleeding resistor 204 to a predetermined value that would make sensing bridge 111 appear as having a lower coupling coefficient with feedback coil 134A than Hall elements 123 have with feedback coil 134B, and then performing a frequency sweep to determine the value of bleeding resistor 202. According to the methodology, a known and stable magnetic field may be applied to sensor 200, starting as an example with a DC field. That will generate a certain output voltage value of signal 141. This value will be the result of the sensing path 120 dominating the output of sensor 200. Next, the frequency of the applied field may be gradually increased. At some point, close to the cross-over frequency (known by design, and which is identified as threshold T in FIG. 1B) the value of signal 141 will start dropping (because of a lower TMR coupling factor K_{fTMR}). Having recorded the output value at low frequencies (corresponding to the hall coupling factor K_{rvH} dominating), and while applying a frequency higher than the cross-over one, the output value is adjusted to match the low-frequency one, by changing and trimming the value of bleeding resistor 202 accordingly.

In the example of FIGS. 2D and 2G, bleeding resistor 202 and/or bleeding resistor 204 are configured to correct for mismatch in the sensitivities of signal paths 310 and 120. According to the present example, the sensitivities of signal paths 310 and 120 are considered mismatched when the gain of signal 118 exceeds the gain of signal 127 by a predetermined threshold amount, or the other way around (when the gain of signal 127 exceeds the gain of signal 118 by a predetermined amount, etc.). In one particular example, the sensitivities of signal paths 310 and 120 are mismatched if the gain of signal 118 differs by more than 5% or 10% from the gain of signal 127. For example, a mismatch in the sensitivities of signal paths 310 and 120 may result from coils 134A-B being supplied with different currents (absent the action of bleeding resistors), a difference in magnetic coupling between coil 134A and MR elements 111 and coil 134B and Hall elements 123, changes in temperature of sensor 200, changes in humidity, changes in mechanical stress that is exerted on sensor 200, and/or for any other reason.

FIG. 3A is a diagram of an example of a sensor 300, according to aspects of the disclosure. Sensor 300 is identical to sensor 100 that is shown in FIG. 1A, but for: (i) the sensor 300 including a second feedback path 230, and (ii) signal path 120 having an amplifier 224 added to it, as well as a current converter 319. As illustrated, amplifier 224 is configured to generate the signal 127 by amplifying the output of low-pass filter 126. Feedback path 230 may include a voltage-to-current (V/I) converter 231, a feedback coil driver 233, and a feedback coil 234. The V/I 231 may be configured to receive the signal 118 and generate a control signal 232. The signal 232 is provided to feedback coil driver 233 where it is used by the feedback coil driver 233 to drive the feedback coil 234. Signal 232 may specify the level of electrical current that is required to be passed through the feedback coil 234 and/or the level of feedback magnetic field that is to be generated by the feedback coil.

In some implementations, current converter 319 may include circuitry that is configured to convert signal 127 from a current signal into a voltage signal. In such implementations, current converter 319 may be a burden resistor and/or any other suitable type of current-to-voltage converter. In other implementations, current converter 319 may include circuitry that is configured to convert signal 127 from a current signal into a different current signal. In such implementations, current converter 319 may be a current mirror or another similar component. Furthermore, in some implementations, current converter 119 may be omitted. Stated succinctly, the present disclosure is not limited to any specific implementation of current converter 319. According to the present example, current converter 319 is a burden resistor that converts a current signal to a voltage signal.

As a result of the feedback path 230 being provided in sensor 100, the stability of the sensitivity of signal path 120 is increased compared to the embodiment of FIG. 1A. On the other hand, in the design of FIG. 2A, the respective gains of signal paths 110 and 120 are required to be matched. This necessitates additional trimming to be performed on the gain of signal path 120 so that it matches the gain of signal path 110. The additional trimming may be performed by adjusting the current used to drive the feedback coils 134 and 234 to correct for any mismatch between the sensitivities of signal paths 110 and 120. In the example of FIG. 3A, amplifier 224 is added in order to provide a high forward gain for feedback path 230.

FIG. 3B is a schematic diagram of sensor 300, according to aspects of the disclosure. FIG. 3B is intended to provide additional detail about the construction of the feedback paths 130 and 230.

In the example of FIG. 3B, sensor 300 includes the sensing path 110, the sensing path 120, the feedback path 130, the feedback path 230 a temperature sensor 190, a controller 187, and a memory 188. The sensing path 110 includes the sensing bridge 111, the sensing path 120 includes the Hall elements 123, feedback path 130 includes the feedback coil 134, the feedback coil driver 133, and the V/I converter 131, and feedback path 230 includes the feedback coil 234, the feedback coil driver 233, and the V/I converter 131.

Temperature sensor 190 may include any temperature sensor that is configured to measure the temperature (e.g., internal temperature or ambient temperature) of sensor 200. Controller 187 may include digital logic, a general-purpose processor, a special-purpose processor, and/or any other suitable type of processing circuitry. Memory 188 may include any suitable type of volatile or non-volatile memory, such as a flash memory or a random-access memory (RAM). Memory 188 may be configured to store configuration settings 189. As is discussed further below, the configuration setting 189 may specify resistance values for bleeding resistors that are part of the feedback path 130.

In the example of FIG. 3B, the feedback coil driver 233 is provided with a bleeding resistor 236. Furthermore, feedback coil driver 233 is provided with a power source 237. The power source 237 may include a voltage source, a current source, and/or any other suitable type of electronic circuitry that is configured to provide, at least in part, the signal that is used to drive the feedback coil 234.

FIG. 3C is a schematic diagram of sensor 300, according to aspects of the disclosure. FIG. 3C is provided to illustrate that feedback coil 134 is arranged to impart a first feedback magnetic field on sensing bridge 111 and feedback coil 234 is arranged to impart a second feedback magnetic field on Hall elements 123. The first feedback magnetic field (generated by feedback coil 134) may be sensed by sensing bridge 111, and ideally not sensed at all (or sensed to a much lesser extent) by Hall elements 123. The second feedback magnetic field (generated by feedback coil 234) may be Hall elements 123, and ideally not sensed at all (or sensed to a much lesser extent) by sensing bridge 111. In other words, feedback coil 134 may be dedicated to influencing the operation of sensing bridge 111, while feedback coil 234 may be dedicated to influencing the operation of Hall elements 123. In the example of FIG. 3C, feedback coil 134 is arranged to surround sensing bridge 111 and feedback coil 234 is arranged to surround Hall elements 123. However, it will be understood that any alternative spatial arrangement can be used instead (in some implementations) in which feedback coil 134 is situated in greater proximity to sensing bridge 111 than Hall elements 123, and feedback coil 234 is situated in greater proximity to Hall elements 123 than sensing bridge 111. In general, feedback coil 134 may be arranged to influence sensing bridge 111 and feedback coil 234 may be arranged to influence Hall elements 123. This means that feedback coils 134 and 234 are so positioned and/or otherwise configured that the magnetic field generated by feedback coil 134 is stronger than the magnetic field generated by feedback coil 234 at the location of sensing bridge 111, and the magnetic field generated by feedback coil 234 is stronger than the magnetic field generated by feedback coil 134 at the location of Hall elements 123. This can be achieved by placing feedback coil 134 in greater proximity to sensing bridge 111 than feedback coil 234 and placing feedback coil 234 in greater proximity to Hall elements 123 than feedback coil 134, and/or in any other suitable manner.

FIG. 3D is a diagram of an example of feedback path 230 that shows feedback coil driver 233 in further detail, according to aspects of the disclosure. In the example of FIG. 3D, bleeding resistor 236 is a variable resistor (or programmable resistor) whose resistance is set by a controller 187. Specifically, the controller 187 is configured to provide bleeding resistor 236 with a signal RES which sets the resistance value of bleeding resistor 202. In the example of FIG. 3D, feedback coil 234 is coupled in series with a resistor 313 and in parallel with the bleeding resistor 236. The power source 237 is configured to supply power (or electrical current) for driving feedback coil 234. As noted above, the level of the supplied current may be set based on signal 232. Signal RES may be generated based on configuration settings 189, in the manner discussed above with respect to FIG. 2D. In the example of FIG. 3D, the bleeding resistor 202 is configured to correct for a mismatch between the sensitivities of signal paths 110 and 120. According to the present example, the sensitivities of signal paths 110 and 120 are considered mismatched when the gain of signal 118 exceeds the gain of signal 127 by a predetermined threshold amount (or when the gain of signal 127 exceeds the gain of signal 118 by the predetermined threshold amount). In one particular example, the sensitivities of signal paths 110 and 120 are mismatched if the gain of signal 118 differs by more than 5% or 10% from the gain of signal 127. For example, a mismatch in the sensitivities of signal paths 110 and 120 may result from coils 134A-B being supplied with different currents (absent the action of bleeding resistors), a difference in magnetic coupling between coil 134A and MR elements 111 and coil 134B and Hall elements 123, changes in temperature of sensor 200, changes in humidity, changes in mechanical stress that is exerted on sensor 200, and/or any other environmental condition that is acting on MR elements 111 and Hall elements 123.

FIG. 3E is a diagram of an example of feedback path 230 that shows feedback coil driver 233 in further detail, according to aspects of the disclosure. In the example of FIG. 3D, bleeding resistor 236 is omitted and power source 237 is a programmable current source. In the present example, the programmable current source is used to correct for a mismatch of in the sensitivities of signal path 110 and signal path 120 that results from changes in temperature (or changes in another environmental condition, such as humidity or stress). The level of the electrical current that is output by the current source 237, which is used to drive the feedback coil 234, is set by controller 187. Specifically, controller 187 is configured to provide the current source 237 with a signal CUR which sets the resistance value of the electrical current that is supplied by the current source 237 to the feedback coil 234. In some implementations, current source 237 may be implemented by using a transconductance amplifier, driven by a voltage generated by the same type of resistor feedback coils 134A-B are made of, to avoid temperature coefficient mismatches.

The value of signal CUR may be specified based on configuration settings 189. In one example, as illustrated by FIG. 3F, configuration settings 189 may be a number that is stored in the memory 188 while sensor 200 is still at the factory. The value of the number may be determined as a result of executing a calibration procedure at the factory where sensor 200 is manufactured. The value of the number may specify the level of electrical current that needs to be used by current source 237 for driving the feedback coil 234.

In another example, as illustrated by FIG. 3G, configuration settings 189 may be a table (or another data structure or database) that maps different current levels to corresponding temperature values. As illustrated, the table may include a plurality of entries 391. Each entry 391 may include a field 392 and a field 393. In the present example, the value of each field 392 is a temperature value, and the value of each field 393 is a current value. In other words, the entries 391 are configured to map each of a plurality of different temperature values to a different corresponding resistance value.

In some implementations, controller 187 may receive a signal TEMP from temperature sensor 300. The entry may be identified in the manner discussed above with respect to FIG. 2F. Next, controller 187 may retrieve, from the identified entry, the value of field 393 (i.e., retrieve the current value that corresponds to signal TEMP). And finally, controller 187 may generate the signal CUR by converting the retrieved value of field 393 to analog format. The signal CUR is then applied to power source 237, which causes power source 237 to assume a state in which outputs an electrical current whose level is the same (or otherwise based on) the value of signal CUR. The term “current value” as used in the context of settings 189, may refer to any number or alphanumerical string that at least in part specifies the current level of signal CUR.

In the example of FIG. 3G, configuration settings 189 maps different temperature values to corresponding current values. However, in alternative implementations, configuration settings 189 may map the values of another environmental condition to corresponding current values. For example, configuration settings may map the resistance values to: (i) humidity values (corresponding to the humidity at the location of sensor 200), (ii) stress values (corresponding to the stress incident on sensor 200), (iii) and/or the values of any another environmental condition that is associated with sensor 200.

FIGS. 1A-3G are provided as an example only. Throughout the disclosure, like reference numerals refer to like parts. The examples provided with respect to FIGS. 1A-3G are not mutually exclusive and may be combined, modified, or adapted in various ways by those skilled in the art without departing from the scope and spirit of the invention defined by the appended claims

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (A_{MR}), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a first signal path having a first gain, the first signal path including a plurality of magnetoresistance (MR) elements, the first signal path being configured to generate a first signal based, at least in part, on an output of the MR elements;
a second signal path having a second gain, the second signal path including one or more Hall elements, the second signal path being configured to generate a second signal based, at least in part, on an output of the Hall elements;
a feedback path that is configured to balance the first gain with the second gain, the feedback path including a first feedback coil, a second feedback coil, and a first variable resistor, the first feedback coil being arranged to influence the plurality of MR elements, the second feedback coil being arranged to influence the Hall elements, the first variable resistor being arranged to at least in part adjust an electrical current that is used to drive at least one of the first feedback coil and the second feedback coil; and
combination circuitry that is configured to generate an output signal based, at least in part, on the first signal with the second signal.

2. The sensor of claim 1, wherein the first variable resistor is configured to at least partially compensate for a mismatch between the sensitivities of the first signal path and the second signal path.

3. The sensor of claim 1, wherein the first feedback coil and the second feedback coil are coupled in series or in parallel to a power source.

4. The sensor of claim 1, further comprising a controller that is configured to set the resistance of the first variable resistor based on information that is stored in a memory of the controller.

5. The sensor of claim 1, further comprising a controller that is configured to set the resistance of the first variable resistor based on an environmental condition that is incident on the sensor.

6. The sensor of claim 1, further comprising a controller that is configured to set the resistance of the first variable resistor based on a temperature of the sensor.

7. The sensor of claim 1, further comprising a controller that is configured to: detect a first value of an environmental condition based on a signal generated by a sensing device that corresponds to the environmental condition, map the first value to a second value, and apply to the first variable resistor a control signal that is generated based on the second value, the control signal setting the resistance of the first variable resistor.

8. The sensor of claim 7, wherein the environmental condition includes temperature.

9. The sensor of claim 1, wherein the combination circuitry includes a subtraction unit that is configured to subtract the second signal from the first signal.

10. The sensor of claim 1, wherein the feedback path further includes a second variable resistor that is arranged to correct the mismatch in magnetic coupling by adjusting an electrical current that is used to drive at least the other one of the first feedback coil and the second feedback coil.

11. A sensor, comprising:
a first signal path having a first gain, the first signal path including a plurality of magnetoresistance (MR) elements, the first signal path being configured to generate a first signal based, at least in part, on an output of the MR elements;
a second signal path having a second gain, the second signal path including one or more Hall elements, the second signal path being configured to generate a second signal based, at least in part, on an output of the Hall elements;
a first feedback coil and a second feedback coil that are configured to balance the first gain with the second gain, the first feedback coil being arranged to influence the plurality of MR elements, and the second feedback coil being arranged to influence the Hall elements;
a variable resistor that is configured to at least in part adjust an electrical current used to drive at least one of the first feedback coil and the second feedback coil; and
combination circuitry that is configured to generate an output signal by combining the first signal with the second signal.

12. The sensor of claim 11, wherein the first variable resistor is configured to at least partially compensate for a mismatch between the sensitivities of the first signal path and the second signal path.

13. The sensor of claim 11, further comprising a controller that is configured to set the resistance of the variable resistor based on information that is stored in a memory of the controller.

14. The sensor of claim 11, further comprising a controller that is configured to set the resistance of the variable resistor based on an environmental condition that is incident on the sensor.

15. The sensor of claim 11, further comprising a controller that is configured to set the resistance of the variable resistor based on a temperature of the sensor.

16. The sensor of claim 11, further comprising a controller that is configured to: detect a first value of an environmental condition based on a signal generated by a sensing device that corresponds to the environmental condition, map the first value to a second value, and apply to the variable resistor a control signal that is generated based on the second value, the control signal setting the resistance of the variable resistor.

17. The sensor of claim 16, wherein the environmental condition includes temperature.

18. The sensor of claim 11, wherein the combination circuitry is configured to add the first signal to the second signal and filter a resulting sum with a filter that is arranged to correct for notching that is present in combined frequency responses of the first signal path and the second signal path.

19. A sensor, comprising:
a first signal path having a first gain, the first signal path including a plurality of magnetoresistance (MR) elements, the first signal path being configured to generate a first signal based, at least in part, on an output of the MR elements;
a second signal path having a second gain, the second signal path including one or more Hall elements, the second signal path being configured to generate a second signal based, at least in part, on an output of the Hall elements;
a first feedback coil and a second feedback coil that are configured to balance the first gain with the second gain, the first feedback coil being arranged to influence the plurality of MR elements, and the second feedback coil being arranged to influence the Hall elements, a variable current source being configured to drive a given one of the first feedback coil and the second feedback coil; and
a controller configured to set a level of an electrical current that is supplied by the variable current source to the given feedback coil in order to cause the first feedback coil and the second feedback coil to balance the first gain with the second gain.

20. The sensor of claim 19, wherein the controller is configured to: detect a first value of an environmental condition based on a signal generated by a sensing device that corresponds to the environmental condition, map the first value to a second value, and apply to the variable current source a control signal that is generated based on the second value, and which sets a level of an electrical current that is supplied by the variable current source to the given feedback coil.
